(19) United States
(12) Patent Application Publication
(10) Pub. No.: US 2024/0371637 A1
(43) Pub. Date: Nov. 7, 2024

(54) METHOD OF MANUFACTURING SEMICONDUCTOR DEVICE

(71) Applicant: INSTITUTE OF MICROELECTRONICS, CHINESE ACADEMY OF SCIENCES, Beijing (CN)

(72) Inventors: Huilong ZHU, Poughkeepsie, NY (US); Zhuo CHEN, Beijing (CN); Jinbiao LIU, Beijing (CN); Junfeng LI, Beijing (CN); Jun LUO, Beijing (CN)

(21) Appl. No.: 18/624,334

(22) Filed: Apr. 2, 2024

(30) Foreign Application Priority Data
May 6, 2023 (CN) 202310505180.8

(51) Int. Cl. H01L 21/02; H01L 21/8234; H01L 27/088

(52) U.S. Cl. CPC H01L 21/02675; H01L 21/823412; H01L 21/823418; H01L 27/088

(57) ABSTRACT

A method of manufacturing a semiconductor device is provided. The method includes: forming a channel defining layer and a source/drain layer sequentially on a substrate of a crystalline material; patterning the channel defining layer and the source/drain layer as a ridge protruding relative to the substrate; forming a channel layer on a sidewall of the ridge by deposition; and performing a crystallization process to recrystallize the channel layer.

This application claims priority to Chinese Patent Application No. 202310505180.8, filed on May 6, 2023, the entire content of which is incorporated herein in its entirety by reference.

### TECHNICAL FIELD

The present disclosure relates to a field of semiconductors, and in particular to a method of manufacturing a semiconductor device for reducing manufacturing costs.

### BACKGROUND

In response to a demand for continuous miniaturization of semiconductor devices, various device structures have been proposed, such as Fin Field Effect Transistors (FinFETs), Multi-Bridge Channel Field Effect Transistors (MBCFETs), Saddle-Fin Field Effect Transistors (Saddle-Fin FETs), etc.

### SUMMARY

According to an aspect of the present disclosure, a method of manufacturing a semiconductor device is provided, including: forming a channel defining layer and a source/drain layer sequentially on a substrate of a crystalline material; patterning the channel defining layer and the source/drain layer as a ridge protruding relative to the substrate; forming a channel layer on a sidewall of the ridge by deposition; and performing a crystallization process to recrystallize the channel layer.

### BRIEF DESCRIPTION OF THE DRAWINGS

The above and other objects, features, and advantages of the present disclosure will become more clear through following description on embodiments of the present disclosure with reference to accompanying drawings, in the drawings:

FIGS. 1 to 21(d) show schematic diagrams of some stages in a process of manufacturing a semiconductor device according to an embodiment of the present disclosure, in which:

FIGS. 2(a), 3(a), 20(a) and 21(a) are top views, FIG. 2(a) shows a position of line AA′, and FIG. 21(a) shows positions of line BB′ and line CC′;

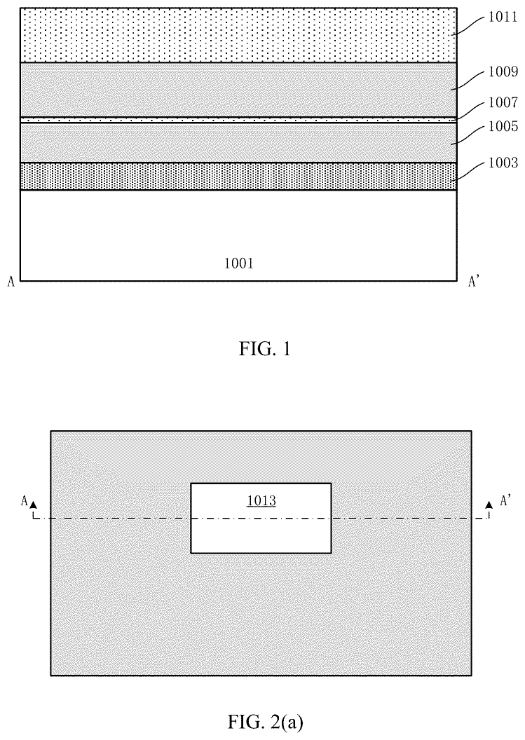

FIGS. 1, 2(b), 3(b), 4 to 19, 20(b) and 21(b) are cross-sectional views taken along line AA′;

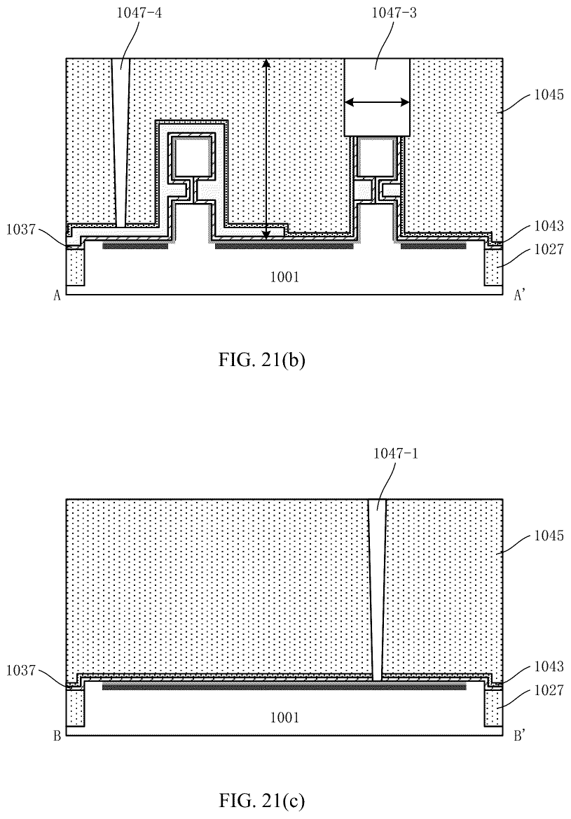

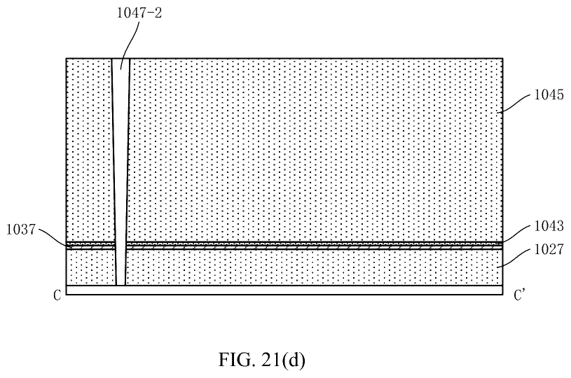

FIG. 21(c) is a cross-sectional view taken along line BB′;

FIG. 21(d) is a cross-sectional view taken along line CC′.

Throughout the accompanying drawings, the same or similar reference numbers indicate the same or similar components. The accompanying drawings are not necessarily drawn to scale, especially the drawing scale of cross-sectional views is different from that of top views for clarity.

### DETAILED DESCRIPTION OF EMBODIMENTS

Hereinafter, embodiments of the present disclosure will be described with reference to accompanying drawings. However, it should be understood that these descriptions are illustrative and not intended to limit the scope of the present disclosure. Further, in the following, descriptions for known structures and technologies are omitted to avoid obscuring the concept of the present disclosure unnecessarily.

Various structures according to embodiments of the present disclosure are shown in the accompanying drawings. However, they are not drawn to scale, and some features may be enlarged while some features may be omitted for sake of clarity. Shapes, relative sizes and positions of regions and layers shown in the drawings are only illustrative, and deviations may occur due to manufacture tolerances or technique limitations in practice. In addition, those skilled in the art may devise regions/layers of other different shapes, sizes, and relative positions as desired in practice.

In the context of the present disclosure, when a layer/element is recited as being “on” a further layer/element, the layer/element may be disposed directly on the further layer/element, or otherwise there may be an intervening layer/element interposed therebetween. Further, if a layer/element is “on” a further layer/element in an orientation, then the layer/element may be “under” the further layer/element when the orientation is turned.

According to an embodiment of the present disclosure, a method of manufacturing a semiconductor device for reducing manufacturing costs is provided.

The semiconductor device according to embodiments of the present disclosure may be a vertical device, such as a vertical nanosheet/nanowire Field Effect Transistor (FET). The vertical device may have a substantially vertically arranged active region, the active region includes a lower source/drain region at a relatively lower vertical height, an upper source/drain region at a relatively higher vertical height, and a channel between the lower source/drain region and the upper source/drain region. The channel may be defined in a substantially vertically extending channel layer. It is desirable that the channel (as well as the lower source/drain region and the upper source/drain region) includes a crystalline material, such as a single crystal material, to improve device performances.

According to an embodiment, the lower source/drain region may be defined by a substrate. Generally, the substrate may be made of a crystalline material, such as a single crystal material. To form a crystal channel and a crystal upper source/drain region above the lower source/drain region, epitaxial growth is usually used in existing processes to grow corresponding (crystal) material layers on the substrate. Different from this, according to an embodiment of the present disclosure, corresponding (amorphous) material layers may be formed on the substrate by deposition, and crystallization process may be performed on the deposited material layers to transform the deposited material layers into crystalline materials, especially single crystal materials. Accordingly, the number of times the epitaxial growth process is used may be reduced.

For example, a channel defining layer and a source/drain layer may be sequentially formed on the substrate by deposition. The channel defining layer defines a position of the channel portion mainly based on a sidewall of the channel defining layer, and may have an etching selectivity relative to the substrate and the source/drain layer for subsequent removal.

The channel defining layer and the source/drain layer may be patterned as a ridge protruding relative to the substrate. When patterning the ridge, etching may be performed in the substrate, so that the substrate has a protruding part corresponding to the source/drain layer. Such ridge has a vertical sidewall, and thus a channel layer may be formed on the sidewall of the ridge by deposition. For example, the channel layer may extend vertically on the sidewall of the channel defining layer (as well as the source/drain layer and the protruding part of the substrate). To facilitate achieving a self-aligned gate structure, selective etching may be used to recess the sidewall of the channel defining layer laterally relative to the sidewall of the source/drain layer (as well as the protruding part of the substrate) before forming the channel layer.

According to an embodiment of the present disclosure, the channel layer may be in an annular shape, and the subsequently formed gate stack may surround the channel layer on inner and outer sides. According to an embodiment, a mask pattern including a hard mask layer and a spacer surrounding a peripheral sidewall of the hard mask layer may be formed. The spacer thus formed may be in a shape of a closed ring surrounding the hard mask layer. When patterning the ridge, such mask pattern may be used as an etching mask. After forming the channel layer on the sidewall of the ridge, an opening may be formed on the inner side of the spacer through the hard mask layer (the source/drain layer and the protruding part of the substrate may be etched together into a ring corresponding to the spacer) to expose the channel defining layer, and thus the channel defining layer may be removed. Therefore, the gate stack may be formed on both inner and outer sides of the channel layer (especially the part of the channel layer on the sidewall of the original channel defining layer).

Source/drain regions may be formed in the substrate (especially the protruding part of the substrate) and the source/drain layer through ion implantation. For example, tilted ion implantation may be performed at lower energy to form a first doping region; vertical ion implantation may be performed at higher energy to form a second doping region below the first doping region. By tilted implantation, ions may enter the vertical surfaces of the source/drain layer and the protruding part of the substrate, as well as the top surface of the source/drain layer and the horizontal surface of the substrate in a region outside the spacer. While, the part of the channel layer on the sidewall of the original channel defining layer may be substantially unaffected due to its relative recess. By vertical implantation, ions may enter the top surface of the source/drain layer and the horizontal surface of the substrate in the region outside the spacer.

According to an embodiment of the present disclosure, the channel layer (as well as the source/drain layer) may be recrystallized by deposition followed by crystallization process, which reduces the use of external growth processes and may thus lower manufacturing costs.

The present disclosure may be presented in various forms, some examples of which will be described below. In the following description, a selection of various materials is involved. In the selection of materials, in addition to a function of the material (for example, a semiconductor material may be used to form an active region, a dielectric material may be used to form an electrical isolation), the etching selectivity is also considered. In the following description, the required etching selectivity may or may not be indicated. It should be clear to those skilled in the art that when etching a material layer is described below, if it is not mentioned or shown that other layers are also etched, then the etching may be selective, and the material layer may have an etching selectivity relative to other layers exposed to the same etching recipe.

FIGS. 1 to 21(d) show schematic diagrams of some stages in a process of manufacturing a semiconductor device according to an embodiment of the present disclosure.

As shown in FIG. 1, a substrate 1001 is provided. The substrate 1001 may be a substrate in various forms, including but not limited to a bulk semiconductor material substrate such as a bulk Si substrate, a Semiconductor On Insulator (SOI) substrate, a compound semiconductor substrate such as a SiGe substrate, or the like. Hereinafter, the bulk Si substrate will be described by way of example for the convenience of description. Here, a silicon wafer is provided as the substrate 1001.

A well region may be formed in the substrate 1001. If a p-type device is to be formed, the well region may be an n-type well. If an n-type device is to be formed, the well region may be a p-type well. In the following, the formation of n-type device is taken as an example for description. Those skilled in the art may understand that the following description also applies to the p-type device, for example, by appropriately adjusting the conductivity type of doping.

For example, the p-type well may be formed by injecting a p-type dopant such as boron (B) into the substrate 1001 followed by thermal annealing. For example, the energy of ion implantation may be in a range of about 30 KeV to 300 KeV, such as 140 KeV. An implantation dose may be in a range of about 1E12/cm² to 1E14/cm², such as 1E13/cm². An implantation angle may be in a range of about 0 degree to 15 degrees, such as 7 degrees. A rotation angle and the number of rotations of the chip during implantation may be 0. In addition, before the ion implantation, a thin film of oxide (such as silicon oxide) with a thickness of about 270 Å may be formed on a surface of the substrate 1001 to protect the surface of the substrate 1001. After ion implantation and annealing, such thin film of oxide may be removed.

A channel defining layer 1003 and a source/drain layer 1005 may be formed on the substrate 1001. The channel defining layer 1003 may be used to define the position of the channel, with a thickness in a range of about 30 nm to 150 nm, such as 80 nm. The source/drain layer 1005 may be used to define the position of the upper source/drain portion, with a thickness in a range of about 30 nm to 200 nm, such as 180 nm.

Considering factors such as etching selectivity in subsequent processes, the channel defining layer 1003 may include nitride (such as silicon nitride), for example. In addition, the source/drain layer 1005 may include amorphous silicon (a-Si), and thus may be crystallized into crystalline silicon in subsequent processes. The channel defining layer 1003 of nitride and the source/drain layer 1005 of amorphous silicon may be formed, for example, by deposition. For example, the channel defining layer 1003 of nitride may be formed by plasma enhanced chemical vapor deposition (PECVD).

According to another embodiment, the channel defining layer 1003 may include SiGe, and the source/drain layer 1005 may include crystalline silicon (c-Si). The channel defining layer 1003 of SiGe and the source/drain layer 1005 of crystalline silicon may be formed by epitaxial growth, for example.

In the following description, the channel defining layer 1003 of nitride and the source/drain layer 1005 of amorphous silicon are mainly taken as examples, and the channel defining layer 1003 of SiGe and the source/drain layer 1005 of crystalline silicon are mentioned when necessary. If not explicitly stated, the following description may apply to both situations.

Next, the active region may be defined from the substrate 1001, the channel defining layer 1003, and the source/drain layer 1005. To avoid photolithography limitations, Spacer Image Transfer is used in the following patterning according to an embodiment of the present disclosure. A mandrel pattern may be formed in order to form a spacer. For example, a mandrel layer 1009 may be formed on the source/drain layer 1005 by deposition, such as chemical vapor deposition (CVD). For example, the mandrel layer 1009 may include a-Si with a thickness in a range of about 50 nm to 450 nm, such as 300 nm. In addition, for better etching control, an etch stop layer 1007 may be formed first by deposition, such as CVD. For example, the etch stop layer 1007 may include oxide with a thickness in a range of about 5 nm to 30 nm, such as 10 nm.

A hard mask layer 1011 may be formed on the mandrel layer 1009 by deposition, such as CVD. For example, the hard mask layer 1011 may include oxides with a thickness in a range of about 50 nm to 450 nm, such as 300 nm.

The mandrel layer 1009 may be patterned as a mandrel pattern.

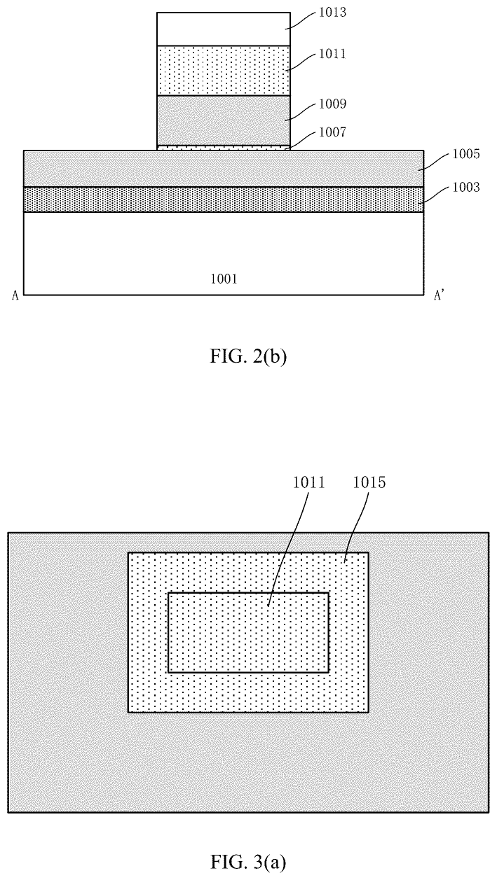

For example, as shown in FIGS. 2(a) and 2(b), a photoresist 1013 may be formed on the hard mask layer 1011 and patterned in a shape corresponding to the active region to be defined through photolithography. In the illustrated example, the photoresist 1013 is patterned into a rectangular shape. However, the present disclosure is not limited to this. For example, the photoresist 1013 may be patterned into other suitable patterns, such as square, circle, ellipse, etc. By using the patterned photoresist 1013 as an etching mask, selective etching may be performed on the hard mask layer 1011, the mandrel layer 1009, and the etch stop layer 1007 in sequence by, such as reactive ion etching (RIE). RIE may be performed in a vertical direction. RIE for the mandrel layer 1009 may stop at the etch stop layer 1007. RIE for the etch stop layer 1007 may stop at the source/drain layer 1005. Afterwards, the photoresist 1013 may be removed.

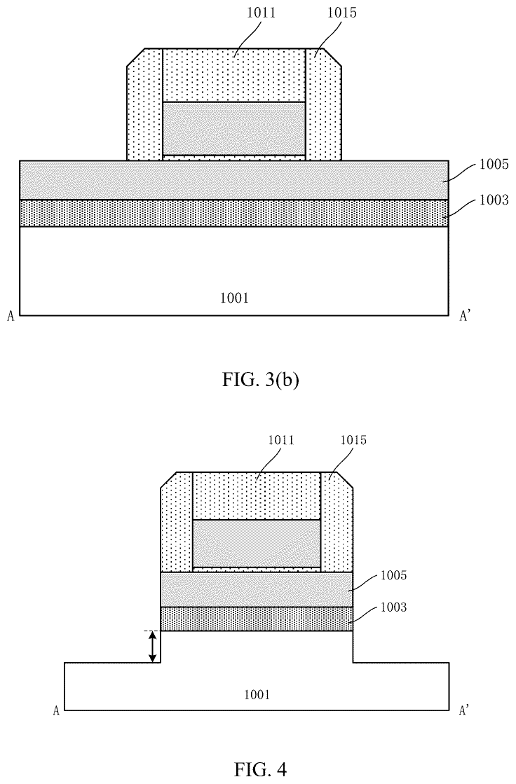

As shown in FIGS. 3(a) and 3(b), a spacer 1015 may be formed on the sidewall of the mandrel layer 1009. For example, oxide may be deposited in a substantially conformal manner, and then anisotropic etching, such as RIE, may be performed on the deposited oxide layer along the vertical direction, to remove a lateral extension part of the oxide layer and leave a vertical extension part of the oxide layer, so as to obtain the spacer 1015. The spacer 1015 may then be used to define the positions of the source/drain regions and the channel portion of the device. A thickness of the spacer 1015 (in the lateral direction) may be in a range of about 20 nm to 250 nm, such as 100 nm. As shown in the figure, the spacer 1015 may be formed in an annular shape surrounding the mandrel layer 1009 (which will subsequently result in an annular channel portion). In addition, the spacer 1015 may extend on the sidewall of the hard mask layer 1011 and the sidewall of the etch stop layer 1007.

In the figure, in order to clearly illustrate the position of the spacer 1015 (for the convenience of readers' understanding), an interface between the spacer 1015 and the hard mask layer 1011 is shown. It should be pointed out that both the spacer 1015 and the hard mask layer 1011 are oxides in this example.

As shown in FIG. 4, the source/drain layer 1005 and the channel defining layer 1003 may be patterned into a ridge by using the hard mask layer 1011 and the spacer 1015. For example, selectively etching, such as RIE in the vertical direction, may be performed on various layers sequentially by using the hard mask layer 1011 and the spacer 1015 as etching masks, so as to transfer the pattern to lower layers. Here, etching may be performed in the substrate 1001, with a depth (as shown by a line segment with arrows in FIG. 4) in a range of about 50 nm to 200 nm, such as 120 nm, so as to improve the shallow trench isolation (STI) oxide indentation process window.

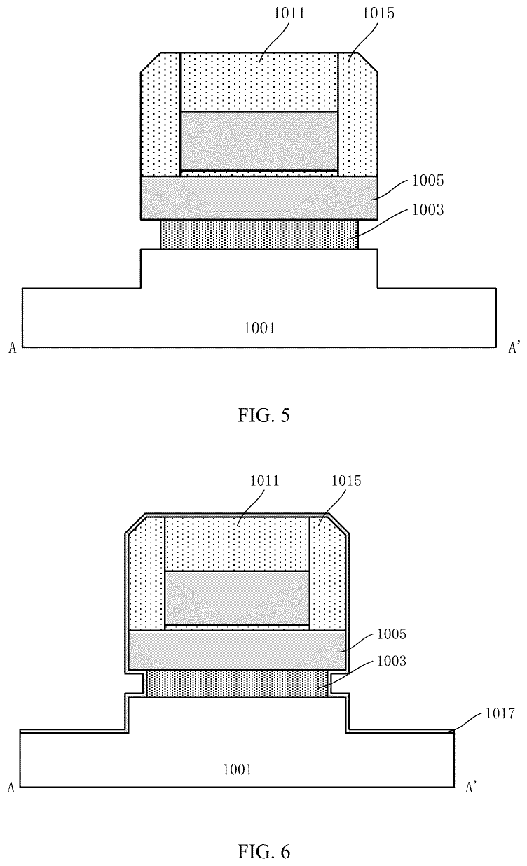

A certain space may be released between the top surface of the substrate 1001 and the source/drain layer 1005, so that (at least part of) the subsequently formed gate stack is provided in such space so as to be self-aligned with the channel portion defined by the channel defining layer 1003. For example, as shown in FIG. 5, selective etching may be performed on the channel defining layer 1003 to recess the sidewall of the channel defining layer 1003 in the lateral direction (such as the horizontal direction within the paper surface in FIG. 5), so as to form a recess portion. Etching may be isotropic dry or wet etching, with lateral etching amount in a range of about 20 nm to 80 nm, such as 50 nm.

In an example shown in FIG. 5, the sidewall of the etched channel defining layer 1003 remains substantially in the vertical direction. Depending on the etching process conditions, the sidewall of the etched channel defining layer 1003 may be in a curved shape, such as a C-shape.

As shown in FIG. 6, an active layer 1017 may be formed by deposition. For example, a covering layer of a-Si may be formed by reduced pressure chemical vapor deposition (RPCVD) or plasma enhanced chemical vapor deposition (PECVD) (in a case of the channel defining layer 1003 of SiGe and the source/drain layer 1005 of c-Si, the covering layer of c-Si may be obtained), and the covering layer of a-Si is split by about 5 nm to 20 nm, such as a-Si (or c-Si) with a thickness of 15 nm, as the active layer 1017. Before deposition, a natural oxide layer may be removed by rinsing with diluted hydrofluoric acid for about 60 seconds. Apart of the active layer 1017 on the sidewall of the channel defining layer 1003 subsequently faces the gate stack, so as to define the channel portion. The channel portion substantially extends in the vertical direction, and thus the active layer 1017 (especially the part of the active layer 1017 on the sidewall of the channel defining layer 1003) may also be referred to as (vertical) channel layer.

In addition, in the case of the channel defining layer 1003 of SiGe and the source/drain layer 1005 of c-Si, in the recess portion of the channel defining layer 1003, the sidewall of the channel defining layer 1003, as well as the top surface of the substrate 1001 and the bottom surface of the source/drain layer 1005 may have single crystal structures and may serve as seed layers when growing the active layer 1017 through CVD, thereby improving the crystal quality of the active layer 1017, especially the crystal quality of a part of the active layer 1017 in the recess portion.

The active layer 1017 is described here using a silicon material as an example. However, the present disclosure is not limited to this. The material of the active layer 1017 may be appropriately selected according to the performance requirements of the device in the design. For example, the active layer 1017 may include various semiconductor materials, such as elemental semiconductor materials such as Ge, or compound semiconductor materials such as SiGe, InP, GaAs, InGaAs, etc.

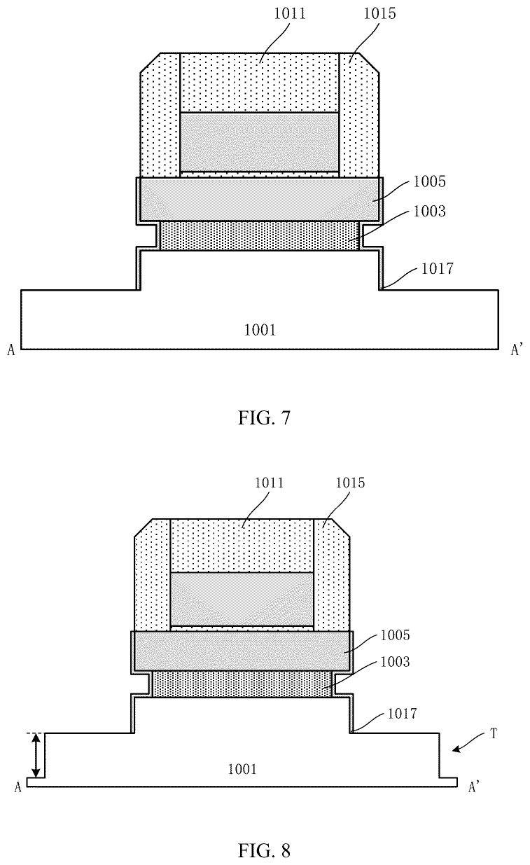

As shown in FIG. 7, corner etching may be performed on the active layer 1017, with an etching amount in a range of about 10 nm to 40 nm, such as 220 Å, to confine the active layer 1017 within the active region, such as extending on the sidewall of the ridge.

In addition, as shown in FIG. 8, trench etching may be performed with an etching depth (as indicated by the line segment with arrows in FIG. 8) of, for example, 220 nm, to form a trench T for STI. The trench T for STI may surround the ridge and define the range of the active region.

Next, the spacer 1015 may be used to define the source/drain region and the channel portion.

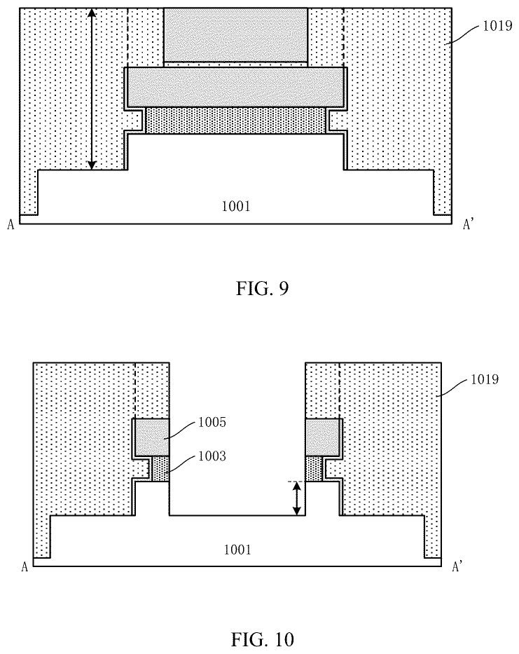

As shown in FIG. 9, a dielectric layer 1019 may be formed on the substrate 1001. For example, the dielectric layer 1019 may include an oxide with a thickness sufficient to fully cover the ridge. For example, an oxide lining layer with a thickness of 10 nm may be formed by deposition, and then an oxide with a thickness in a range of about 700 nm to 1200 nm, such as 1100 nm, may be formed by high-area rapid printing (HARP). According to an embodiment, in order to reduce the stress caused by the deposition of thicker oxides (which may cause chip warping), printing may be performed in batches. For example, an oxide with a thickness in a range of about 200 nm to 400 nm, such as 350 nm, may be formed, and then an oxide with a thickness in a range of about 500 nm to 800 nm, such as 750 nm, may be formed. After each printing, heat process may be performed to reduce or even eliminate the stress. Then, planarization such as chemical mechanical polishing (CMP) may be performed on the deposited oxide to remove the hard mask layer 1011 and thus expose the mandrel layer 1009. For example, after planarization, the thickness of the dielectric layer 1019 (measured from the upper surface of the substrate 1001 in the region surrounded by the trench T for STI, as shown by the line segment with arrows in FIG. 9) may be in a range of about 580 nm to 640 nm, such as 640 nm.

In the figure, the etch stop layer 1007 and the spacer 1015, which are oxides, are shown integrated with the dielectric layer 1019 for convenience. (Possible) interfaces therebetween are illustrated by dashed lines in FIG. 9.

As shown in FIG. 10, the mandrel layer 1009 may be removed by selective etching (which may stop at the etch stop layer 1007), such as wet etching using TMAH solution. Then, an opening (corresponding to a region surrounded by the closed annular spacer 1015) is formed in the dielectric layer 1019.

The etch stop layer 1007, the source/drain layer 1005, the channel defining layer 1003, and the substrate 1001 may be selectively etched sequentially through such opening, for example, by RIE in the vertical direction. In this way, below the original spacer 1015 (now shown as integrated with the dielectric layer 1019), the source/drain layer 1005, the channel defining layer 1003, the protruding part of the substrate 1001, and the active layer 1017 form a closed ring corresponding to the spacer 1015. Here, the etching depth of the substrate 1001 (as shown by the line segment with arrows in FIG. 10) is in a range of about 100 nm to 180 nm, such as 120 nm, which may be substantially identical to etching depth (see FIG. 4) of the substrate 1001 on the outer side of the spacer 1015. Considering the load effect of etching, a target etching depth set in the etching process may be increased. For example, a target etching depth of about 145 nm may be set to achieve an actual etching depth of about 120 nm. In this way, in the active region surrounded by the trench T for STI, except for the part of the substrate 1001 vertically overlapping with the spacer 1015, the substrate 1001 may have upper surfaces substantially located at the same level. The part of the substrate 1001 vertically overlapping with the spacer 1015 may protrude about 120 nm relative to the upper surface of the remaining part of the substrate 1001.

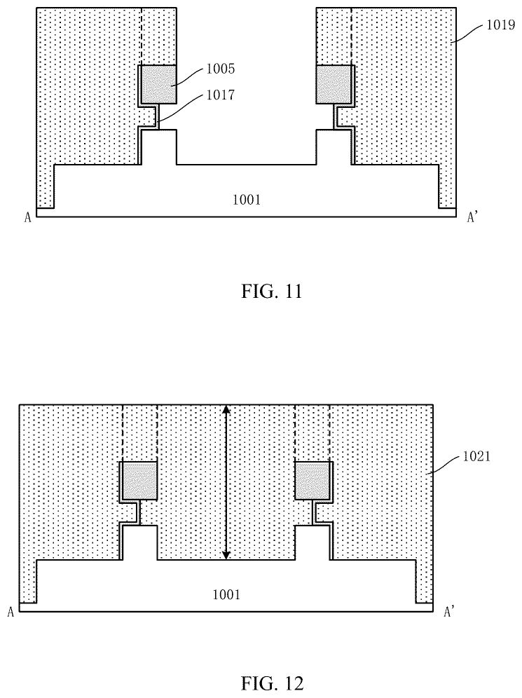

The active layer 1017 is covered by the channel defining layer 1003 on the inner side. The channel defining layer 1003 (nitride in this example) may be removed by selective etching, such as soaking in hot phosphoric acid for about 15 minutes, relative to the substrate 1001, the source/drain layer 1005, and the active layer 1017 (all of which are Si in this example), leaving a space for the gate stack on the inner side of the active layer 1017, as shown in FIG. 11.

Oxide may be filled on the inner side of the spacer 1015, so that the active region under the spacer 1015 may be surrounded by oxide on both inner and outer sides, and thus have substantially the same processing conditions on both inner and outer sides.

For example, as shown in FIG. 12, similar to the formation of the dielectric layer 1019 as described in FIG. 9 above, an oxide lining layer with a thickness in a range of about 5 nm to 15 nm, such as 10 nm, may be formed by deposition. Then, an oxide with a thickness in a range of about 700 nm to 1000 nm, such as 750 nm, may be formed by HARP. Then, planarization such as CMP may be performed on the deposited oxide. Here, the planarized oxide is integrated with the previously formed dielectric layer 1019, which is also an oxide, as shown as 1021 (dashed lines are still retained in the figure to indicate the position of the spacer 1015). The thickness of the planarized dielectric layer 1021 (measured from the upper surface of the substrate 1001 in the region surrounded by the trench T for STI, as shown by the line segment with arrows in FIG. 12) may be in a range of about 580 nm to 680 nm, such as 640 nm. In this way, the dielectric layer 1021 may cover the source/drain layer 1005.

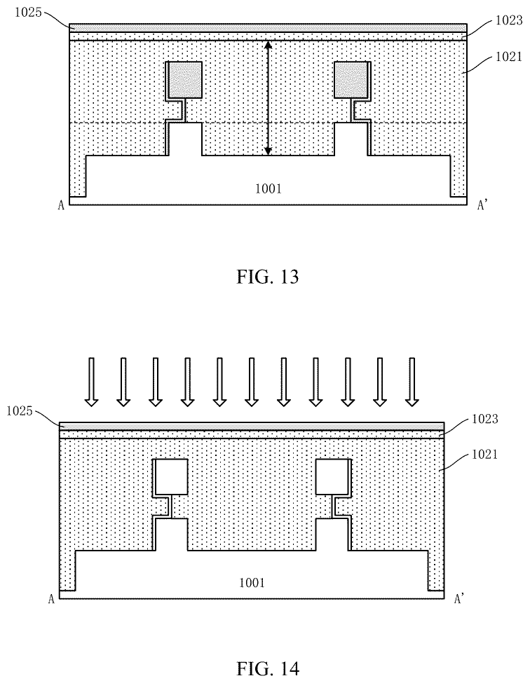

As shown in FIG. 0.13, the thickness of the dielectric layer 1021 may be reduced by selective etching, for example. The reduced thickness of the dielectric layer 1021 is measured from the upper surface of the substrate 1001 in the region surrounded by the STI trench, as shown by the line segment with arrows in FIG. 13. According to an embodiment, in order to test the effect of the dielectric layer 1021 with different thicknesses (causing different stresses) on recrystallization, samples of dielectric layer 1021 with different thicknesses, such as 395 nm, 420 nm, 445 nm, or 470 nm, may be fabricated. According to the test, the thickness of the dielectric layer 1021 may be in a range of about 280 nm to 420 nm, preferably 420 nm.

In addition, a cap layer may be formed on the dielectric layer 1021, for example, by deposition, to adjust the stress. The cap layer may include, for example, an oxide lining layer 1023 with a thickness of about 100 Å and a nitride layer 1025 with a thickness of about 100 Å. The nitride layer 1025 may be formed through PECVD. The cap layer (such as the nitride layer therein) may include a compressive stress film and/or a tensile stress film, so as to achieve a stress on the active layer 1017 being in a range of −5 GPa to 5 GPa, preferably a compressive stress of 1.5 GPa, before achieving recrystallization.

As shown in FIG. 14, a crystallization process may be performed on the source/drain layer 1005 and the active layer 1017 (both including a-Si or c-Si) by an annealing process, for example, to recrystallize the source/drain layer 1005 and the active layer 1017, thereby transforming a-Si into crystalline materials such as polycrystalline silicon or monocrystalline silicon, or further improving the crystal quality of c-Si. For example, the crystallization process may be performed by: a laser annealing with an intensity in a range of about 1 J/cm² to 2 J/cm²; a furnace annealing at a temperature in a range of about 600° C. to 900° C. for about 1 hour to 10 hours; or a rapid thermal processing (RTP) at a temperature in a range of about 1000° C. to 1100° C. for about 1 millisecond (ms) to 1 second (s).

In the laser annealing process, different laser depths may be used for samples of the dielectric layer 1021 with different thicknesses. The laser depth may be determined according to the seeds or templates in the crystallization process. In this example, the top surface of the substrate 1001 may be used as the seed or template for the crystallization process, so the laser depth may be at or near the top surface of the substrate 1001 as shown by the dashed line in FIG. 13. For example, when the thickness of the dielectric layer 1021 is, for example, 395 nm, 420 nm, 445 nm, or 470 nm, the laser depth may be 275 nm, 300 nm, 325 nm, or 350 nm, respectively.

During crystallization, the top surface of the substrate 1001 in contact with the active layer 1017 may serve as the seed or template (in the case of the channel defining layer 1003 of SiGe and the source/drain layer 1005 of c-Si, the bottom surface of the source/drain layer 1005 of c-Si in contact with the active layer 1017 may also be used as the seed or template). As shown in FIG. 14, the source/drain layer 1005′ and the active layer 1017′ after the crystallization process are shown at the same grayscale as the substrate 1001, to illustrate that they may include crystalline silicon with the same or substantially the same structure as the substrate 1001.

In this way, the vertical extension part of the active region is defined, including the protruding part of the substrate 1001, the active layer 1017′, and the source/drain layer 1005′ (as a whole, presenting a ring defined by the spacer 1015), all of which may be crystalline materials such as single crystal materials. Through this process, the use of epitaxial growth process may be reduced, thereby reducing manufacturing costs.

The manufacturing of the device may be completed by using the active region thus defined, especially the vertical extension part of the active region, as the basis.

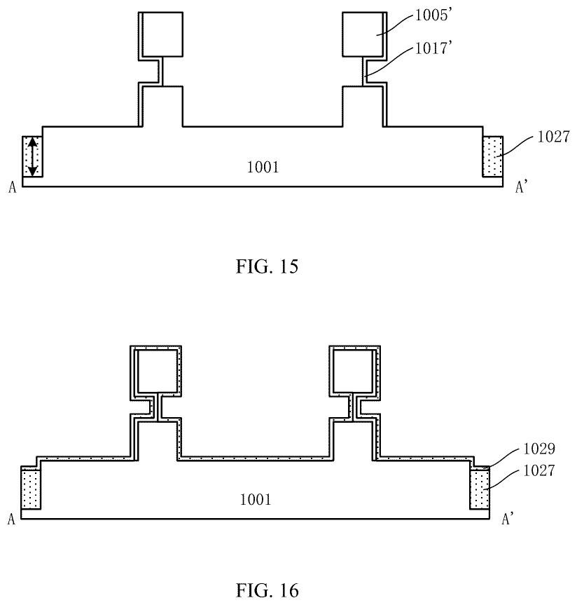

For example, as shown in FIG. 15, the nitride layer 1025 in the cap layer may be removed by selecting etching, so that the oxide lining layer 1023 and the dielectric layer 1021 of oxide in the cap layer are further lowered, leaving them in the trench T for STI, so as to form STI 1027. A thickness of the STI 1027 (as shown by the line segment with arrows in FIG. 15) may be in a range of about 170 nm to 200 nm, for example. As described above, the STI 1027 may surround the active region.

The active region may be doped to form the source/drain regions.

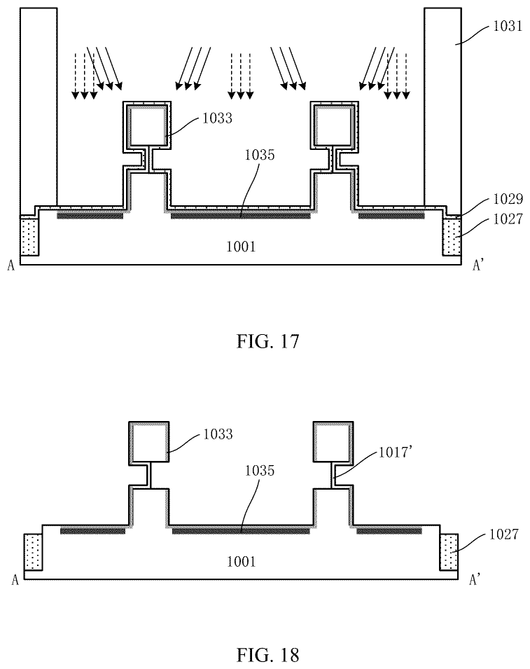

In order to protect the surface of the active region, as shown in FIG. 16, an oxide lining layer 1029 with a thickness of about 100 Å may be formed. Then, as shown in FIG. 17, a photoresist 1031 may be formed and patterned through photolithography to shield the STI 1027 and expose the active region. Considering the process margin, the photoresist 1031 may shield an edge region of the active region near the STI 1027. The photoresist 1031 may be sufficiently high, for example, exceeding 1 μm, so that ion implantation may be performed on the active region within a cavity thus defined (the angle of ion implantation may be limited, for example, ions at a larger angle relative to the normal direction of the substrate may be shielded by the photoresist 1031). As shown by the solid arrows in the figure, tilted ion implantation may be performed to form a doping region 1033 along the surface of the active region. For example, n-type impurities such as arsenic (As) may be implanted by tilted ion implantation with 10° relative to the normal direction of the substrate, an energy of about 2 KeV, and a dose of about 2E15 cm⁻². Due to the small tilt angle, such ion implantation may substantially not affect the middle of the channel layer 1017′, that is, the channel portion. Accordingly, the channel portion may remain in an unintentional doping state.

In addition, as shown by the dashed arrows in the figure, vertical ion implantation may be performed to form a lightly doping region 1035 near the upper surface of the substrate 1001 in the active region. For example, n-type impurities such as phosphorus (P) may be implanted by vertical ion implantation with 0° relative to the normal direction of the substrate, an energy of about 4 KeV, and a dose of about 4E14 cm⁻². Due to the high energy of the vertical ion implantation, the doping region 1035 may be formed below the doping region 1033 (and may adjoin the doping region 1033). Due to the vertical implantation, the doping region 1033 may be almost not formed on the sidewall of the vertical part of the active region, and may be formed near the top surface (the top surface of the source/drain layer 1005′) of the vertical part of the active region, for example, also below the doping region 1033 (but not shown in the figure). In addition, due to the small dosage of the vertical ion implantation, the doping concentration in the doping region 1035 may be lower than that in the doping region 1033. Afterwards, the photoresist 1031 may be removed.

As shown in FIG. 18, impurities in the doping regions 1033 and 1035 may be activated by annealing, such as a peak annealing at a temperature of about 1050° C., so as to form the source/drain regions. In addition, before annealing, an oxide lining layer (not shown in the figure) with a thickness of about 20 nm may be formed by deposition, such as PECVD, to better protect the active region during annealing. After annealing, the oxide lining layer 1029 (as well as the deposited oxide lining layer) may be removed by rinsing with diluted hydrofluoric acid for about 8 minutes (after annealing, the rate at which the oxide is etched by diluted hydrofluoric acid is for example 55 Å/minute).

In this way, the definition of the active region, especially the source/drain regions and the channel portion therein, has been completed. The gate stack may be formed on the active region thus defined to complete device manufacturing.

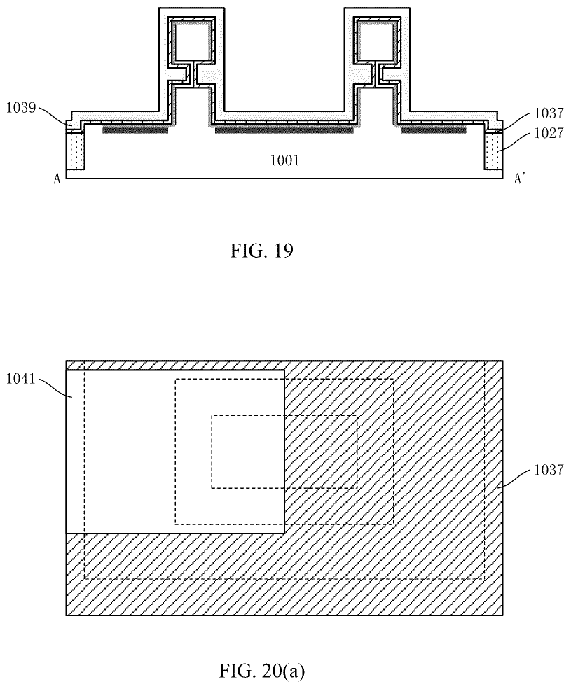

For example, as shown in FIG. 19, a gate dielectric layer 1037 may be formed by deposition in a substantially conformal manner, and a gate conductor layer 1039 may be formed on the gate dielectric layer 1037. The gate dielectric layer 1037 may include a high k gate dielectric. For example, in the deposition process, 3 cycles of alumina deposition and 32 cycles of hafnium oxide deposition may be performed to form the gate dielectric layer 1037. In addition, before forming the high k gate dielectric, an interface layer may further be formed, such as an oxide formed through oxidation processes or deposition such as atomic layer deposition (ALD). The gate conductor layer 1039 may include a metal gate, such as a work function adjustable metal such as TiN with a thickness of about 20 Å, and a gate conductive metal such as W with a thickness of about 300 Å. Before forming the gate stack, a single piece cleaning machine may be used to spray diluted hydrofluoric acid for about 40 seconds to remove any natural oxides that may exist on the surface.

As shown in the figure, the gate stack (the gate dielectric layer 1037 and the gate conductor layer 1039) thus formed is embedded between the top surface of the substrate 1001 and the bottom surface of the source/drain layer 1005′, and may thus be self-aligned with the channel portion (the part between the upper and lower source/drain regions) in the active layer 1017′.

The gate stack, especially the gate conductor layer 1039 therein, may be appropriately patterned to facilitate the fabrication of various contact plugs.

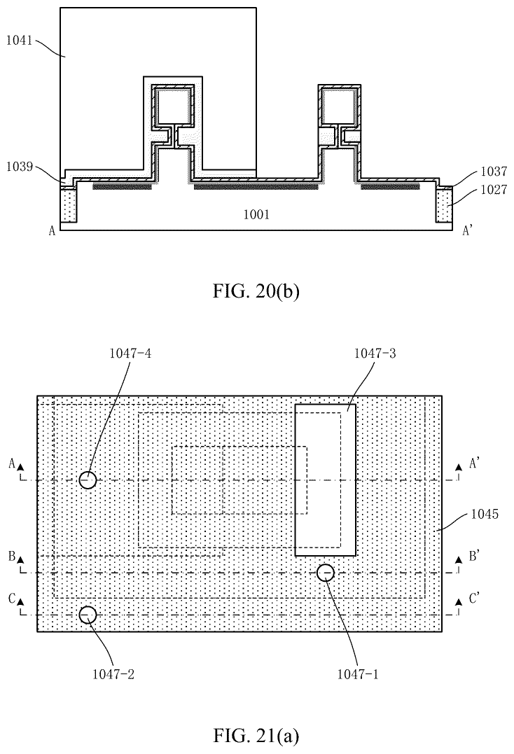

For example, as shown in FIGS. 20(a) and 20(b), a photoresist 1041 may be formed on the gate conductor layer 1039, and patterned by photolithography to cover a part of the gate conductor layer 1039. The photoresist 1041 may be patterned to shield a part of the region where the original spacer 1015 is located (to shield the gate conductor layer therein), and extend a certain range from such region, as well as expose: another part of the region where the original spacer 1015 is located (in which a contact plug to the upper source/drain region may be formed), a part of the upper surface of the substrate 1001 in the active region (in which a contact plug to the lower source/drain region may be formed), and a part of the region of the STI (in which a contact plug to the well region in the substrate 1001 may be formed). In the illustrated example, the photoresist 1041 is shown as a rectangle. However, the present disclosure is not limited to this. The photoresist 1041 may be patterned into any other patterns suitable for manufacturing. The dashed lines in FIG. 20(a) schematically illustrate the region of the STI (in other words, the region of the active region) and the region where the upper source/drain region (the original spacer 1015 as well as defined by the original spacer 1015) is located. For example, the outermost dashed line indicates the (partial) boundary between the STI and the active region, that is, the region outside the dashed line is the STI, and the region inside the dashed line is the active region surrounded by the STI; the two concentric rectangular dashed lines on the inside indicate the region where the upper source/drain region (the original spacer 1015 as well defined by as the original spacer 1015) is located.

Selectively etching such as RIE may be performed on the gate conductor layer 1039 by using the patterned photoresist 1041 as a mask. The etching may stop at the gate dielectric layer 1037. Therefore, except for a region of the gate conductor layer 1039 covered by the photoresist 1041, the gate conductor layer 1039 is removed from the gate dielectric layer 1037. Afterwards, the photoresist 1041 may be removed.

As shown in FIGS. 21(a), 21(b), 21(c) and 21(d), a dielectric layer may be formed on the substrate 1001 and a contact plug may be formed within the dielectric layer. For example, in order to better control etch stop positions of contact holes, a lining layer 1043 with a thickness of about 15 nm, such as nitride, may be formed by deposition. An interlayer dielectric layer 1045 may be obtained by depositing a dielectric such as TEOS on the lining layer 1043 and performing the planarization such as CMP on the deposited dielectric. The thickness of the interlayer dielectric layer 1045 (the height above the upper surface of the substrate 1001 in the active region, as shown by the vertical line segment with arrows in FIG. 21(b)) may be about 620 nm, for example.

In the region where there is no gate conductor layer 1039 on the upper surface of the substrate 1001 in the active region (outside the region where the original spacer 1015 is located), for example, a contact hole may be formed by etching based on photolithography, and a contact plug 1047-1 for the lower source/drain region may be formed in the contact hole. When etching the contact hole, the interlayer dielectric layer 1045 may be selectively etched, and the etching may stop at the lining layer 1043; then, the lining layer 1043 and the gate dielectric layer 1037 may be selectively etched sequentially. The lower source/drain region (for example, the doping region 1033) may be exposed at the bottom of the contact hole. The contact plug 1047-1 may be formed by filling the etched contact hole with a conductive material. The contact plug 1047-1 may be in contact with the doping region 1033 exposed at the bottom of the contact hole.

Similarly, in the region where there is no gate conductor layer 1039 in the STI region, for example, a contact hole may be formed by etching based on photolithography, and a contact plug 1047-2 for the well region may be formed in the contact hole. When etching the contact hole, the interlayer dielectric layer 1045 may be selectively etched, and the etching may stop at the lining layer 1043; then, the lining layer 1043, the gate dielectric layer 1037, and the STI 1027 may be selectively etched sequentially. (The well region in) the substrate 1001 may be exposed at the bottom of the contact hole. The contact plug 1047-2 may be formed by filling the etched contact hole with a conductive material. The contact plug 1047-2 may be in contact with the well region exposed at the bottom of the contact hole.

Similarly, in the region where there is no gate conductor layer 1039 in the region where the original spacer 1015 is located, for example, a contact hole may be formed by etching based on photolithography, and a contact plug 1047-3 for the upper source/drain region may be formed in the contact hole. When etching the contact hole, the interlayer dielectric layer 1045 may be selectively etched, and the etching may stop at the lining layer 1043; then, the lining layer 1043 and the gate dielectric layer 1037 may be selectively etched sequentially. The upper source/drain region (for example, the doping region 1033) may be exposed at the bottom of the contact hole. The contact plug 1047-3 may be formed by filling the etched contact hole with a conductive material. The contact plug 1047-3 may be in contact with the doping region 1033 exposed at the bottom of the contact hole. Considering the subsequently electrical connection, the contact plug 1047-3 may be formed as a rectangle with a width (as indicated by the horizontal line with arrows in FIG. 21(b)) of about 0.5 μm, as shown in the cross-sectional view.

Similarly, in the region where the gate conductor layer 1039 is located, for example, a contact hole may be formed by etching based on photolithography, and a contact plug 1047-4 for the gate conductor layer may be formed in the contact hole. When etching the contact hole, the interlayer dielectric layer 1045 may be selectively etched, and the etching may stop at the lining layer 1043; then, the lining layer 1043 may be selectively etched. The gate conductor layer 1039 may be exposed at the bottom of the contact hole. The contact plug 1047-4 may be formed by filling the etched contact hole with a conductive material. The contact plug 1047-4 may be in contact with the gate conductor layer 1039 exposed at the bottom of the contact hole.

It is noted that the above etchings for forming various contact holes are performed separately in the interlayer dielectric layer 1045, because their respective etching depths are different. Their etching orders may be different from the orders described above.

The filling of corresponding contact plugs in each contact hole may be performed through the same process steps after all contact holes are etched. For example, a barrier layer such as a conductive nitride such as TiN may be formed in a substantially conformal manner, and then a conductive material such as a metal such as tungsten (W) may be deposited. Planarization such as CMP may be performed to expose the top surface of the interlayer dielectric layer 1045, so that the barrier layer and the conductive material may remain in the contact hole to form the contact plug. In addition, before filling the contact hole with the contact plug, dilute hydrofluoric acid may be used for rinsing for about 90 seconds to remove a natural oxide with a thickness in a range of about 2 nm to 3 nm.

Next, subsequent processes may be performed, which will not be repeated here.

The semiconductor device according to embodiments of the present disclosure may be applied to various electronic apparatuses. Therefore, the present disclosure further provides an electronic apparatus including the semiconductor device described above. The electronic apparatus may further include components such as a display screen and a wireless transceiver. The electronic apparatus may include, for example, a smart phone, a personal computer (PC), a tablet computer, a wearable intelligence apparatus, an artificial intelligence apparatus, and a mobile power supply.

According to an embodiment of the present disclosure, a method of manufacturing a system on chip (SoC) is further provided. This method may include the above-mentioned method. Specifically, a variety of devices may be integrated on the chip, at least some of which are manufactured according to the method of the present disclosure.

In the above descriptions, technical details such as patterning and etching of each layer have not been described in detail. However, those skilled in the art should understand that various technical means may be used to form layers, regions, etc. of desired shapes. In addition, in order to form the same structure, those skilled in the art may also design a method that is not completely the same as the method described above. In addition, although the various embodiments are described above separately, this does not mean that the measures in the various embodiments may not be advantageously used in combination.

Embodiments of the present disclosure have been described above. However, these embodiments are for illustrative purposes only, and are not intended to limit the scope of the present disclosure. The scope of the present disclosure is defined by the appended claims and their equivalents. Without departing from the scope of the present disclosure, those skilled in the art may make various substitutions and modifications, and these substitutions and modifications should all fall within the scope of the present disclosure.

What is claimed is:

1. A method of manufacturing a semiconductor device, comprising:
forming a channel defining layer and a source/drain layer sequentially on a substrate of a crystalline material;
patterning the channel defining layer and the source/drain layer as a ridge protruding relative to the substrate;
forming a channel layer on a sidewall of the ridge by deposition; and
performing a crystallization process to recrystallize the channel layer.

2. The method according to claim 1, wherein an etching is performed into the substrate when patterning the ridge, so that the substrate has a protruding part corresponding to the source/drain layer, and
wherein before forming the channel layer, the method further comprises:
selective etching the channel defining layer, so that a sidewall of the channel defining layer is laterally recessed relative to a sidewall of the source/drain layer and a sidewall of the protruding part of the substrate.

3. The method according to claim 2, wherein after forming the channel layer, the method further comprises:
etching a central part of the ridge while retaining a peripheral part of the ridge, so that the source/drain layer, the channel defining layer, and the protruding part of the substrate are in an annular shape; and
removing the channel defining layer through selective etching.

4. The method according to claim 1, further comprising:
forming a dielectric layer on the substrate to cover the substrate, the ridge, and the channel layer; and
fabricating samples with dielectric layers of different thicknesses, and testing an effect of the thickness of the dielectric layer on the crystallization process.

5. The method according to claim 3, wherein after performing the crystallization process, the method further comprises:
performing a tilted ion implantation with a first energy, so as to form a first doping region; and
performing a vertical ion implantation with a second energy higher than the first energy, so as to form a second doping region below the first doping region.

6. The method according to claim 3,
wherein patterning the ridge comprises:
forming a mandrel layer on the source/drain layer and forming a hard mask layer on the mandrel layer;
patterning the hard mask layer and the mandrel layer;
forming a spacer on a peripheral sidewall of the mandrel layer and a peripheral sidewall of the hard mask layer; and
selectively etching, by using the hard mask layer and the spacer as an etching mask, the source/drain layer and the channel defining layer sequentially, and selectively etching a part of the substrate, and
wherein etching the central part of the ridge comprises:
forming a dielectric layer on the substrate to cover a region outside the ridge;
performing a planarization process on the dielectric layer, the spacer, and the hard mask layer to expose the mandrel layer; and
removing the mandrel layer by selective etching, and further etching downwards into the substrate to expose the channel defining layer.

7. The method according to claim 3, further comprising:
forming a gate stack, wherein the gate stack comprises a part between a top surface of the substrate and a bottom surface of the source/drain layer, so as to surround the channel layer on inner and outer sides of the channel layer.

8. The method according to claim 1, further comprising:
forming a dielectric layer on the substrate to cover the substrate, the ridge, and the channel layer; and
forming a cap layer on the dielectric layer to adjust a stress.

9. The method according to claim 8, wherein the cap layer comprises a compressive stress film and/or a tensile stress film, so as to achieve that a stress on the channel layer is in a range of −5 GPa to 5 GPa before the crystallization process.

10. The method according to claim 9, wherein the stress on the channel layer is a compressive stress of 1.5 GPa.

11. The method according to claim 8, wherein the dielectric layer comprises an oxide, and the cap layer comprises an oxide lining layer and a nitride layer.

12. The method according to claim 4, wherein a thickness of the dielectric layer is in a range of about 280 nm to 420 nm.

13. The method according to claim 12, wherein the thickness of the dielectric layer is 420 nm.

14. The method according to claim 1, wherein the crystallization process comprises one of:
a laser annealing with an intensity in a range of about 1 J/cm² to 2 J/cm²;
a furnace annealing at a temperature in a range of about 600° C. to 900° C. for about 1 hour to 10 hours; or
a rapid thermal processing at a temperature in a range of about 1000° C. to 1100° C. for about 1 millisecond to 1 second.

15. The method according to claim 14, wherein in the laser annealing, a laser depth is near a top surface of the substrate adjoining the channel layer.

16. The method according to claim 1, wherein the channel defining layer comprises a dielectric material, and the source/drain layer comprises a semiconductor material, the channel defining layer and the source/drain layer are formed by deposition; or
the channel defining layer comprises a semiconductor material, and the source/drain layer comprises a semiconductor material, the channel defining layer and the source/drain layer are formed by epitaxial growth, and
wherein the channel defining layer has an etching selectivity relative to the substrate and the source/drain layer.

17. The method according to claim 2, further comprising:
forming a dielectric layer on the substrate to cover the substrate, the ridge, and the channel layer; and
fabricating samples with dielectric layers of different thicknesses, and testing an effect of the thickness of the dielectric layer on the crystallization process.

18. The method according to claim 3, further comprising:
forming a dielectric layer on the substrate to cover the substrate, the ridge, and the channel layer; and
fabricating samples with dielectric layers of different thicknesses, and testing an effect of the thickness of the dielectric layer on the crystallization process.

19. The method according to claim 2, further comprising:
forming a dielectric layer on the substrate to cover the substrate, the ridge, and the channel layer; and
forming a cap layer on the dielectric layer to adjust a stress.

20. The method according to claim 3, further comprising:
forming a dielectric layer on the substrate to cover the substrate, the ridge, and the channel layer; and
forming a cap layer on the dielectric layer to adjust a stress.
